(19) United States
(12) Patent Application Publication
(10) Pub. No.: US 2024/0282550 A1
(43) Pub. Date: Aug. 22, 2024

(54) BLANKING APERTURE ARRAY SYSTEM AND CHARGED PARTICLE BEAM WRITING APPARATUS

(71) Applicant: NuFlare Technology, Inc., Yokohama-shi (JP)

(72) Inventors: Kei HASEGAWA, Yokohama-shi (JP); Hayato KIMURA, Sunto-gun (JP)

(73) Assignee: NuFlare Technology, Inc., Yokohama-shi (JP)

(21) Appl. No.: 18/635,723

(22) Filed: Apr. 15, 2024

Related U.S. Application Data
(63) Continuation of application No. PCT/JP2022/033750, filed on Sep. 8, 2022.

(30) Foreign Application Priority Data
Nov. 22, 2021 (JP) 2021-189582

(51) Int. Cl. H01J 37/30; H01J 37/304; H01J 37/317

(52) U.S. Cl. CPC H01J 37/3007; H01J 37/304; H01J 37/3177; H01J 2237/0435

(57) ABSTRACT

A blanking aperture array system includes a data output circuit that outputs first data and a first error detection code generated from the first data. A shift register transfers the first data and first error detection code that are input from the data output circuit. A buffer receives the first data from a first register. An electrode receives a voltage based on the first data output from the buffer. An error detection circuit receives the first data and first error detection code from a register of a last stage, generates a second error detection code from the first data received from the register of the last stage, and generate a detection signal indicating a match if the first error detection code from the register of the last stage and the second error detection code match and indicating a mismatch if they do not match.

### CROSS-REFERENCE TO RELATED APPLICATIONS

This application is a Continuation Application of PCT Application No. PCT/JP2022/33750, filed Sep. 8, 2022 and based upon and claiming the benefit of priority from Japanese Patent Application No. 2021-189582, filed Nov. 22, 2021, the entire contents of all of which are incorporated herein by reference.

### FIELD

Embodiments generally relate to a blanking aperture array system and a charged particle beam writing apparatus.

### BACKGROUND

Masks are used in the manufacture of semiconductor devices. In order to form a fine element, a mask pattern is also required to be fine. In order to form a mask having a fine pattern, a pattern is written on a material of the mask using an electron beam. In order to efficiently form a mask, a writing method using a plurality of electron beams (a multi-beam writing method) may be used.

In the multi-beam writing method, an electron beam is caused to pass through a mask (shaping aperture array plate) having a plurality of apertures, and multiple beams are formed. The multiple beams are directed to a blanking aperture array mechanism having a plurality of apertures. Each beam is individually deflected by the blanking aperture array mechanism, and the deflected beam hits a shield and does not reach the mask.

Around each aperture, the blanking aperture array mechanism includes a mechanism for deflecting a beam passing through the aperture. The mechanism includes electrodes and elements of an electronic circuit for applying a voltage to the electrodes. The electronic circuit transmits data, which is supplied from the outside of the blanking aperture array mechanism, for controlling the blankers of the blanking aperture array mechanism and generates a voltage to be applied to the electrodes.

The electron beam radiation for writing may damage elements of the electronic circuit in the blanking aperture array mechanism. The accumulation of damage may degrade the characteristics of the elements. If the degradation in characteristics exceeds a certain critical point, the elements of the electronic circuit may fail, in which case the blanking aperture array mechanism will not be able to operate correctly. By way of example, a failure of the electronic circuit may result in the data for controlling the blanking aperture not being transmitted correctly. In addition, since a large amount of data is transferred at a high speed with miniaturization, transfer abnormality may occur in rare cases even if the bit error rate is low. Since the mask has a very fine pattern, a failure to transmit even a single bit of data can create a defect in the mask.

To avoid this, the blanking aperture array mechanism can be diagnosed before writing. If a fault is discovered at the time of diagnosis, it can be dealt with before writing. However, since the writing apparatus is almost always operating, the above-described abnormality probably occurs in the middle of writing in many cases. If a failure is detected during the writing, the failure can be dealt with by, for example, changing the control so as to compensate the failure. Therefore, a technique for detecting a failure during writing is desired.

On the other hand, writing requires a large amount of data to be transmitted at a high speed, and interruption of writing for detection of a failure is not desired. Therefore, a charged particle beam apparatus is desired which can detect a failure during writing in a manner that does not hinder writing as much as possible. In addition, since a large amount of data is transmitted at a high speed in the multi-beam system, data may change even if the bit error rate is low.

### BRIEF DESCRIPTION OF THE DRAWINGS

According to one embodiment, a blanking aperture array system used in a multi-charged particle beam irradiation apparatus includes a data output circuit, a shift register, a buffer, an electrode, and an error detection circuit. The data output circuit is configured to output first data, which is one of a plurality of control data items used in beam irradiation, and a first error detection code for detecting an error in the first data generated from the first data. The shift register includes a plurality of registers connected in series and is configured to transfer the first data and the first error detection code that are input from the data output circuit. The buffer is configured to receive the first data that is output from a first register from the first register. The first register is one of the plurality of registers. The electrode is configured to receive a voltage based on the first data that is output from the buffer. The error detection circuit is configured to receive the first data and the first error detection code from a register of a last stage among the plurality of registers, generate a second error detection code for detecting an error in the first data from the first data received from the register of the last stage; and generate a detection signal indicating a match if the first error detection code from the register of the last stage and the second error detection code match and indicating a mismatch if the first error detection code from the register of the last stage and the second error detection code do not match.

FIG. 1 shows elements of a writing apparatus according to a first embodiment.

FIG. 2 shows a hardware configuration of a control device according to the first embodiment.

FIG. 3 shows a structure of a shaping aperture array plate of the first embodiment along the xy plane.

FIG. 4 shows a structure of a blanking aperture array mechanism of the first embodiment along the xz plane.

FIG. 5 shows the structure of the blanking aperture array mechanism of the first embodiment along the xy plane.

FIG. 6 shows circuitry and associated elements of the blanking aperture array mechanism of the first embodiment.

FIG. 7 shows some elements and connections of a control circuit of the first embodiment, and related elements.

FIG. 8 shows a part of FIG. 7.

FIG. 9 schematically shows data transfer and generation in the writing apparatus of the first embodiment.

FIG. 10 shows some elements and connections of the control circuit of a second embodiment, and related elements.

FIG. 11 schematically shows the transfer and generation of data in the writing apparatus of the second embodiment.

### DETAILED DESCRIPTION

Embodiments will now be described with reference to the figures. In the following description, components with substantially the same functionalities and configurations will be referred to with the same reference symbols, and repeated descriptions may be omitted. In order to distinguish components having substantially the same function and configuration from each other, an additional numeral or letter may be added to the end of each reference numeral.

The entire description of a particular embodiment applies to another embodiment unless an explicit mention is made otherwise, or an obvious elimination is involved. It is not necessary that functional blocks be distinguished as in the following examples. For example, some of the functions may be implemented by functional blocks different from those illustrated below. Furthermore, an illustrated functional block may be divided into functional sub-blocks.

The embodiments will be described using an xyz orthogonal coordinate system.

### 1. First Embodiment

### 1.1. Structure (Configuration)

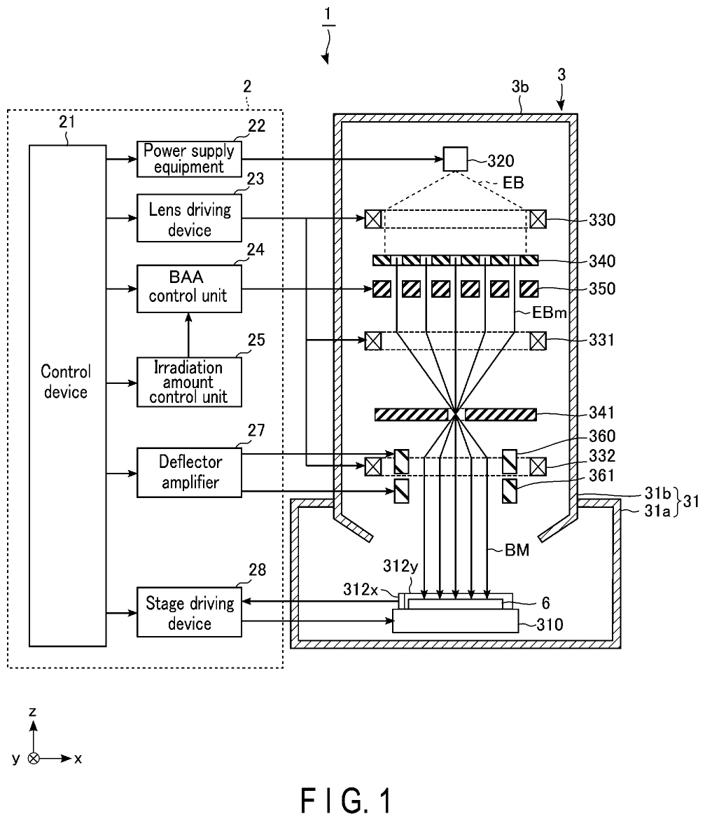

FIG. 1 shows elements (configuration) of a writing apparatus according to the first embodiment. A writing apparatus 1 is, for example, a multi-charged particle beam writing apparatus. Some elements are described in more detail below.

The writing apparatus 1 includes a control circuit system 2 and a writing mechanism 3. The writing mechanism 3 generates a charged particle beam and irradiates a sample 6 with the generated charged particle beam to draw a pattern on the sample 6. Examples of the sample 6 include a mask coated with a resist and a reticle. The control circuit system 2 controls the operation of the writing mechanism 3.

The writing mechanism 3 includes a vacuum chamber 31. The inside of the vacuum chamber 31 is kept in a vacuum state, for example, during writing on the sample 6 by the writing apparatus 1. The vacuum chamber 31 is constituted by a writing chamber 31a and a lens barrel 31b.

The writing chamber 31a has, for example, a rectangular parallelepiped shape and has a space therein. The writing chamber 31a contains a sample 6. The writing chamber 31a has an opening in the upper surface, and is connected to the internal space of the lens barrel 31b at the opening.

The writing apparatus 1 also includes a stage 310 in the writing chamber 31a. The sample 6 is placed on the upper surface of the stage 310 during writing. The stage 310 can move along the x axis and the y axis while holding the sample 6 substantially horizontally. A mirror 312x and a mirror 312y are provided on the upper surface of the stage 310. The mirror 312x extends along the y-axis, and the mirror 312y extends along the x axis. The mirrors 312x and 312y are used as references for detection of the position of the stage 310.

The lens barrel 31b has a cylindrical shape extending along the z axis and is made of, for example, stainless steel. The lower end of the lens barrel 31b is located inside the writing chamber 31a. The writing apparatus 1 further includes, in the lens barrel 31b, an electron gun 320, an illumination lens 330, a reduction lens 331, an objective lens 332, a shaping aperture array plate 340, a limiting aperture array plate 341, a blanking-aperture array mechanism (blanking-aperture array system, blanking-aperture array substrate) 350, and deflectors 360 and 361.

The electron gun 320 is located in an upper portion of the inside of the lens barrel 31b. The electron gun 320 is, for example, a hot cathode electron gun, and includes elements such as a cathode, a Wehnelt electrode, and an anode. Upon receipt of a voltage, the electron gun 320 emits an electron beam EB downward along the z axis (in the −z direction). The electron beam EB spreads along the xy plane as it travels along the z axis.

The illumination lens 330 is an annular electromagnetic lens and is located below the electron gun 320 along the z axis. The illumination lens 330 shapes the electron beam EB that has reached the illumination lens 330 and spreads in the xy plane so that the electron beam EB travels in parallel along the z axis.

The shaping aperture array plate 340 is located below the illumination lens 330 along the z axis. The shaping aperture array plate 340 has a plurality of apertures, and causes a part of the electron beam EB incident on the shaping aperture array plate 340 to pass through the plurality of apertures and to be branched into a plurality of electron beams EBm.

The blanking aperture array mechanism 350 is located below the shaping aperture array plate 340 along the z axis (in the −z direction). The blanking aperture array mechanism 350 individually blanks the plurality of electron beams EBm. The blanking aperture array mechanism 350 includes a plurality of apertures respectively located below the openings of the shaping aperture array plate 340 along the z axis (in the −z direction), and blankers provided around each aperture. Each blanker blanks the electron beam EBm incident on the target aperture provided with the blanker.

The reduction lens 331 is an annular electromagnetic lens and is located below the blanking aperture array mechanism 350 along the z axis (in the −z direction). The reduction lens 331 focuses a plurality of electron beams EBm parallel to each other, which have passed through the blanking aperture array mechanism 350, on the center of the aperture of the limiting aperture array plate 341.

The limiting aperture array plate 341 has a plate shape extending along the xy plane, and has an aperture at the center of the xy plane. The aperture is located near the convergence point (crossover point) of the plurality of electron beams EBm that have passed through the reduction lens 331. The beam deflected by the blanker provided in the blanking aperture array mechanism 350 cannot pass through the aperture provided in the center of the limiting aperture array plate 341, and strikes the limiting aperture array plate 341 to be blanked. The limiting aperture array plate 341 shapes the electron beams EBm along the xy plane by causing the plurality of electron beams EBm to pass through apertures. The plurality of shaped electron beams EBm form a shot having a certain shape.

The deflector 360 is located below the limiting aperture array plate 341 along the z axis (in the −z direction). The shot-shaped electron beam EBm emitted from the limiting aperture array plate 341 is incident on the deflector 360. The deflector 360 includes a plurality of pairs of electrodes. In FIG. 1, only one pair of electrodes is shown to avoid unnecessary complication of the drawing. The two electrodes constituting each pair are opposed to each other. Each electrode receives a voltage, and the deflector 360 deflects the incident electron beam EBm along the x-axis and/or the y axis in response to the application of the voltage to the plurality of electrodes.

The objective lens 332 is an annular electromagnetic lens and surrounds the deflector 360. The objective lens 332 focuses the electron beam EBm on a specific position of the sample 6 in conjunction with the deflector 360.

The deflector 361 is located below the deflector 360 along the z axis (in the −z direction). The electron beam EBm that has passed through the deflector 360 is incident on the deflector 361. The deflector 361 includes a plurality of pairs of electrodes. In FIG. 1, only one pair of electrodes is shown to avoid unnecessary complication of the drawing. The two electrodes constituting each pair are opposed to each other. Each electrode receives a voltage, and the deflector 361 deflects the incident electron beam EBm along the x axis and/or the y axis in response to the application of the voltage to the plurality of electrodes.

The control circuit system 2 includes a control device 21, power supply equipment 22, a lens driving device 23, a BAA control unit 24, an irradiation amount control unit 25, a deflector amplifier 27, and a stage driving device 28.

The control device 21 controls the power supply equipment 22, the lens driving device 23, the BAA control unit 24, the irradiation amount control unit 25, the deflector amplifier 27, and the stage driving device 28. The control device 21 receives an input from, for example, a user of the writing apparatus 1, and controls the power supply equipment 22, the lens driving device 23, the BAA control unit 24, the irradiation amount control unit 25, the deflector amplifier 27, and the stage driving device 28 based on the received input.

The power supply equipment 22 receives control data from the control device 21 and applies a voltage to the electron guns 320 based on the control data received from the control device 21.

The lens driving device 23 receives control data from the control device 21 and controls the illumination lens 330 based on the received control data. Specifically, the lens driving device 23 controls the intensity of the illumination lens 330 with respect to the electron beam EB, that is, the intensity of refraction of the electron beam EB. The lens driving device 23 controls the intensity of the illumination lens 330 so that the electron beam EB which is incident on the illumination lens 330 from above the z-axis of the illumination lens 330 and spreads along the xy plane as it travels is shaped into an electron beam substantially parallel to the z axis.

The lens driving device 23 also receives control data from the control device 21, and controls the intensity of the reduction lens 331 based on the received control data. The lens driving device 23 controls the intensity of the reduction lens 331 such that the electron beam EBm incident on the reduction lens 331 from above the z axis of the reduction lens 331 without being blanking-deflected by the blanker of the blanking aperture array mechanism 350 is focused on the center of the aperture of the limiting aperture array plate 341.

The lens driving device 23 further receives control data from the control device 21, and controls the intensity of the objective lens 332 based on the received control data. The lens driving device 23 controls the intensity of the objective lens 332 so that the electron beam BM incident on the objective lens 332 from above the z axis of the objective lens 332 is focused on the upper surface of the sample 6. The lens driving device 23 may reduce the electron beam BM.

The BAA control unit 24 receives BAA control data from the control device 21 and controls the blanking aperture array mechanism 350 based on the received control data.

The irradiation amount control unit 25 receives control data from the control device 21, and generates irradiation amount control data based on the received control data. The irradiation amount control unit 25 supplies the generated irradiation amount control data to the BAA control unit 24 and controls the irradiation amount of the electron beam BM with respect to the sample 6 via the BAA control unit 24.

The deflector amplifier 27 receives control data from the control device 21, and generates control signals for controlling the deflectors 360 and 361, respectively, based on the received control data. The generated control signals are supplied to the deflectors 360 and 361, respectively. The signal for the deflector 360 specifies the potential difference between the two electrodes of each pair of the deflector 360. Similarly, the signal for the deflector 361 specifies the potential difference between the two electrodes of each pair of the deflector 361. The deflector amplifier 27 generates a signal for the deflector 360 so that the deflector 360 receives a voltage that deflects the electron beam EBm by an amount and/or a direction designated by the control device 21. Similarly, the deflector amplifier 27 generates a signal for the deflector 361 so that the deflector 361 receives a voltage that deflects the electron beam EBm by an amount and/or direction designated by the control device 21.

The stage driving device 28 measures the positions of the mirrors 312x and 312y using a unit such as a laser sensor (not shown), and detects the position of the stage 310 based on the measured positions. The stage driving device 28 receives control data from the control device 21, and drives the stage 310 based on the received control data. The sample 6 is moved to a desired position by driving the stage 310.

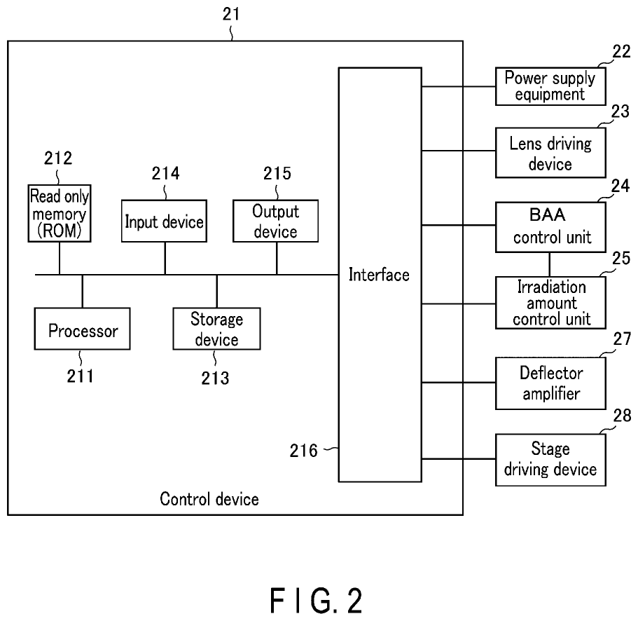

FIG. 2 shows a configuration of the control device 21 of the first embodiment, particularly a configuration of hardware. As shown in FIG. 2, the control device 21 includes a processor 211, a read only memory (ROM) 212, a storage device 213, an input device 214, an output device 215, and an interface 216.

The ROM 212 stores a program for controlling the processor in a nonvolatile manner. The storage device 213 includes a volatile memory, a nonvolatile memory, and/or a hard disk, and holds data. The processor 211 is, for example, a central processing unit, and performs various operations by executing a program stored in the ROM 212 and loaded onto the storage device 213. The processor 211 controls the storage device 213, the input device 214, the output device 215, and the interface 216 in accordance with a program. The program is configured to cause the control device 21, particularly the processor 211, to perform various operations.

The input device 214 includes one or more of a keyboard, a mouse, or a touch panel, and enables a user of the writing apparatus 1 to input instructions and/or parameters. The output device 215 includes a display and presents various kinds of information to the user of the writing apparatus 1. The interface 216 controls communication between the control device 21 and the power supply equipment 22, the lens driving device 23, the BAA control unit 24, the irradiation amount control unit 25, the deflector amplifier 27, and the stage driving device 28.

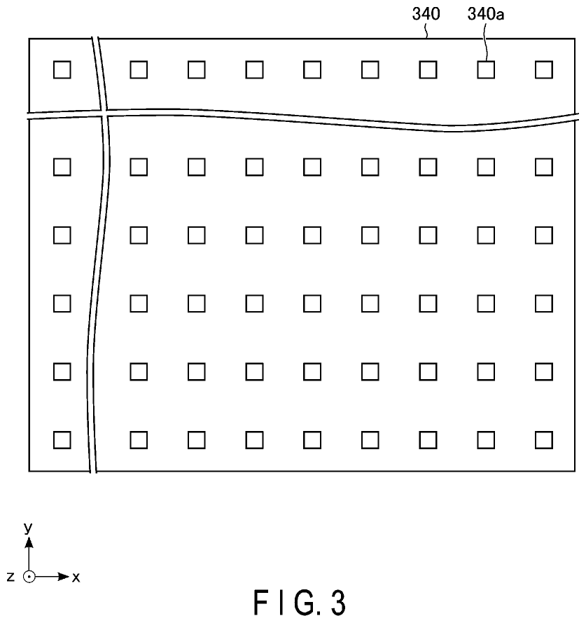

FIG. 3 schematically shows the structure of the shaping aperture array plate 340 of the first embodiment along the xy plane. As shown in FIG. 3, the shaping aperture array plate 340 extends along the xy plane and has, for example, a rectangular shape. The shaping aperture array plate 340 has, for example, silicon as a base, and the surface of the base is covered with a thin film. The thin film is, for example, chromium, and can be formed by plating or sputtering. The shaping aperture array plate 340 has a plurality of apertures 340a. The aperture 340a penetrates two surfaces of the shaping aperture array plate 340 that face each other along the z axis, namely a top surface and a bottom surface. The apertures 340a are arranged in a matrix along the x axis and the y axis, for example. The apertures 340a are, for example, square and have substantially the same shape as each other.

The electron beam EB emitted from the electron gun 320 is shaped by the illumination lens 330 so as to be parallel to the z axis, and is incident on the upper surface of the shaping aperture array plate 340. A part of the incident electron beam EB is blocked by the shaping aperture array plate 340, and the rest of the electron beam EB passes through the apertures 340a. By such selective blocking and passage of the electron beam EB, the electron beam EB is divided (multiplexed) into a plurality of electron beams EBm traveling downward along the z-axis.

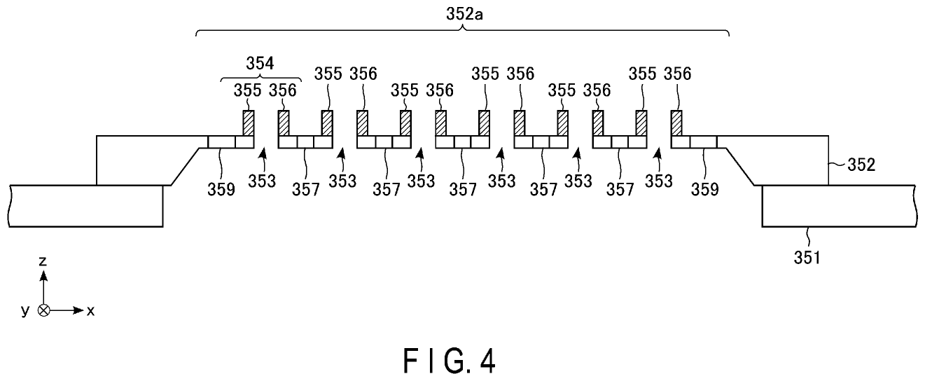

FIG. 4 shows the structure of the blanking aperture array mechanism 350 of the first embodiment along the xz plane. As shown in FIG. 4, the blanking aperture array mechanism 350 includes a base 351. The base 351 extends along the xy plane.

The substrate 352 is provided on the upper surface of the base 351. The substrate 352 is made of, for example, a semiconductor such as silicon. The substrate 352 is located on the upper surface of the substrate 351 at the edge of the bottom surface and is thinner at the central portion 352a than at the edge. The substrate 352 also includes a plurality of apertures 353 in the central portion 352a. Each aperture 353 spans the top and bottom surfaces of the substrate 352. The apertures 353 are arranged in the xy plane. Each aperture 353 is located below one aperture 340a of the shaping aperture array plate 340 along the z axis, and has, for example, a shape similar to the shape of the aperture 340a in the xy plane, and is slightly larger than the shape of the aperture 340a in the xy plane. The center of each aperture 353 substantially coincides with the center of an aperture 340a of the shaping aperture array plate 340 on the xy plane. The aperture 353 allows the beam EBm that has passed through the aperture 340a of the shaping aperture array plate 340 to pass.

The blanking aperture array mechanism 350 also includes a plurality of electrode pairs 354. Each pair of electrodes 354 is provided for one aperture 340a, includes electrodes 355 and 356, and functions as a blanker. The electrodes 355 and 356 contain or consist of copper, for example. The electrodes 355 and 356 of each electrode pair 354 are spaced apart from each other and sandwich one aperture 353 for which the electrode pair 354 is provided.

Each control circuit 357 is provided in a portion between neighboring electrode pairs 354 (between the electrode 356 of a certain electrode pair 354 and the electrode 355 of an adjacent electrode pair 354) on the substrate 352. Each control circuit 357 is provided for one electrode pair 354. Each control circuit 357 receives various control signals and applies a voltage to one electrode pair 354 for which the control circuit 357 is provided based on the received control signal. Each control circuit 357 includes a plurality of elements such as transistors and resistors formed on the substrate 352.

The data output circuit 359 is provided at the end of the central portion 352a of the substrate 352. Each data output circuit 359 receives the control data DLS from the BAA control unit 24 and outputs the control data DL in a format different from that of the control data DLS in parallel from the received control data DLS. The data output circuit 359 includes a plurality of elements such as transistors and resistors formed on the substrate 352.

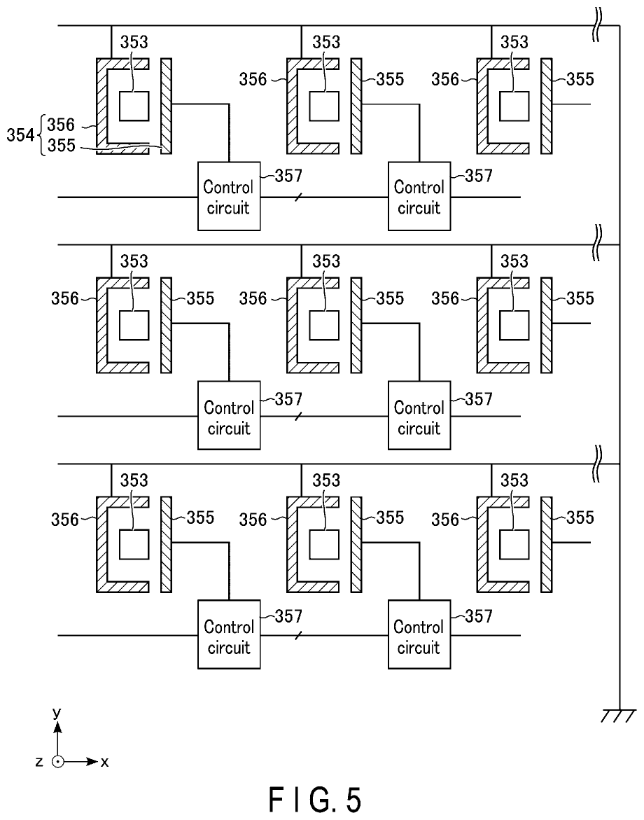

FIG. 5 shows the structure of the blanking aperture array mechanism 350 of the first embodiment along the xy plane. As shown in FIG. 5, each electrode 356 has a shape obtained by removing one side from a rectangle. The three sides of the electrode 356 extend along the three sides of the aperture 353 surrounded by the electrode 356. FIG. 5 shows, as an example, a structure in which each electrode 356 extends along two sides of the aperture 353 parallel to the x axis and the left side of two sides of the aperture 510 parallel to the y axis.

Each electrode 355 extends along a side along which the electrode 356 constituting the electrode pair 354 together with the electrode 355 does not extend, among sides of the corresponding aperture 353. FIG. 5 shows a structure in which each electrode 355 extends along the right side of the two sides parallel to the y axis.

The electrode 356 is grounded. Each electrode 355 is electrically connected to one control circuit 357 corresponding to the electrode 355.

Each control circuit 357 receives various control signals as described above. The control signal includes a clock signal and control data DL. The control signal is supplied from the BAA control unit 24. The control circuit 357 is also connected to a node of an internal power supply potential VCC (for example, 5 V).

Each of the electrodes 356 is connected to a node of a common (ground) potential VSS (e.g., 0 V).

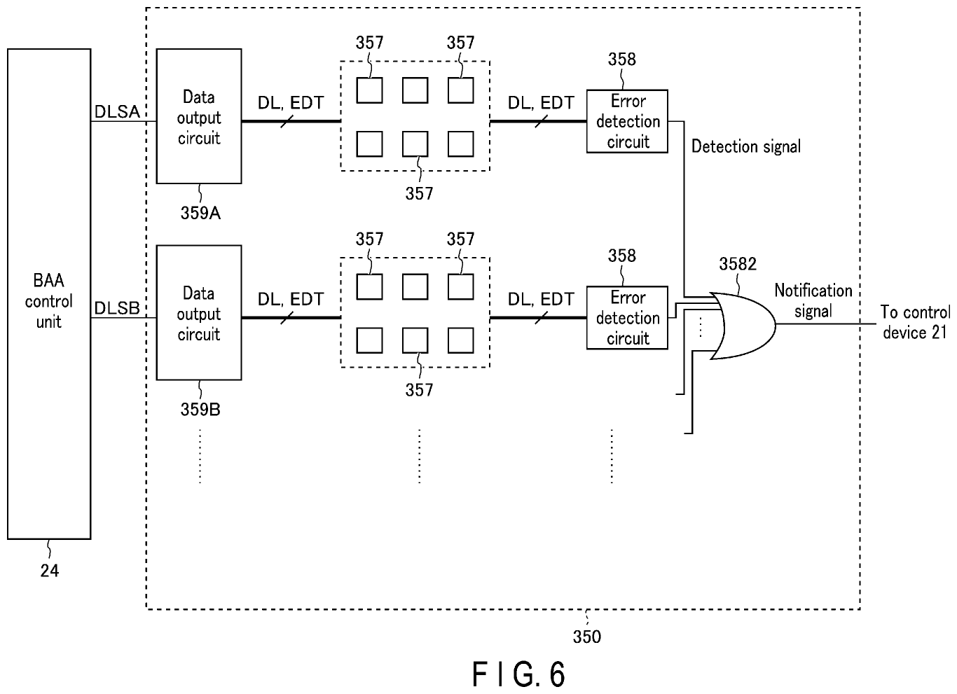

FIG. 6 is a circuit diagram of the blanking aperture array mechanism 350 of the first embodiment, and further shows related elements. As shown in FIG. 6, the blanking aperture array mechanism 350 includes a plurality of data output circuits 359 (359A, 359B, . . . ). Each data output circuit 359 receives a clock from the BAA control unit 24 and receives control data DLS (DLSA, DLSB, . . . ) for the data output circuit 359. That is, the data-output circuit 359A receives the control data DLSA from the BAA control unit 24, and the data output circuit 359B receives the control data DLSB from the BAA control unit 24. The same applies to the other data output circuits 359. The control data DLS consists of a plurality of bits.

Each data output circuit 359 is connected to a set of control circuits 357. Each data output circuit 359 outputs a plurality of sets of control data DL in parallel based on the received control data DLS. Each data output circuit 359 outputs an error detection code EDT for certain control data DL. In the present embodiment, the error detection code EDT is described as being generated by the data output circuit 359, but may be generated by the BAA control unit 24. The error detection code EDT output by the data output circuit 359 is received by the error detection circuit 358 connected to the data output circuit 359 via the control circuits 357. This received error detection code EDT is referred to as a “transmitted error detection code EDT” hereinafter.

The control data DL is supplied to the set of control circuits 357. The blanking aperture array mechanism 350 further includes error detection circuits 358 and logical sum (OR) gates 3582 provided in the same number as the number of data output circuits 359 included in the blanking aperture array mechanism 350. Each control circuit 357 includes a register as described below, and the set of control circuits 357 can transfer data via the registers. The control circuit 357 will be described later in detail.

Each error detection circuit 358 is provided for a certain set of control circuits 357, and is connected to a certain plurality of control circuits 357 in the set of control circuits 357. The details of the connection between the error detection circuit 358 and the corresponding set of control circuits 357 will be described later.

Each error detection circuit 358 receives control data DL from the plurality of control circuits 357 connected to the error detection circuit 358. Each error detection circuit 358 receives certain control data DL and a transmitted error detection code EDT for the control data DL from the data output circuit 359 via the control circuit 357. Each error detection circuit 358 detects an error in the received control data DL based on the received control data DL and the transmitted error detection code EDT. The details are as follows.

Each error detection circuit 358 generates an error detection code from the received data, i.e., the control data DL, by a certain method. The technique that may be used may be of any type, and examples of such a technique include cyclic redundancy check (CRC) and checksum. Hereinafter, the error detection code generated by the error detection circuit 358 will be referred to as a “calculated error detection code EDC”.

The transmitted error detection code EDT and the calculated error detection code EDC for certain control data DL should match if the control data DL is correctly transmitted from the data output circuit 359 to the error detection circuit 358. Based on this fact, the error detection circuit 358 compares the transmitted error detection code EDT with the calculated error detection code EDC.

If the transmitted error detection code EDT for certain control data DL and the calculated error detection code EDC do not match, the error detection circuit 358 outputs a detection signal indicating the mismatch. The detection signal is, for example, a digital signal, and a high level indicates detection of a mismatch.

The OR gate 3582 receives the detection signals from all the error detection circuits 358. If any one of the received detection signals has a high level, the OR gate 3582 outputs a high-level notification signal indicating that an error has been detected. The notification signal that is output by the OR gate 3582 is transmitted to the control device 21. If the control device 21 receives the notification signal indicating that an error has been detected, the control device 21 notifies the user of the error detection using, for example, the output device 215 of FIG. 2.

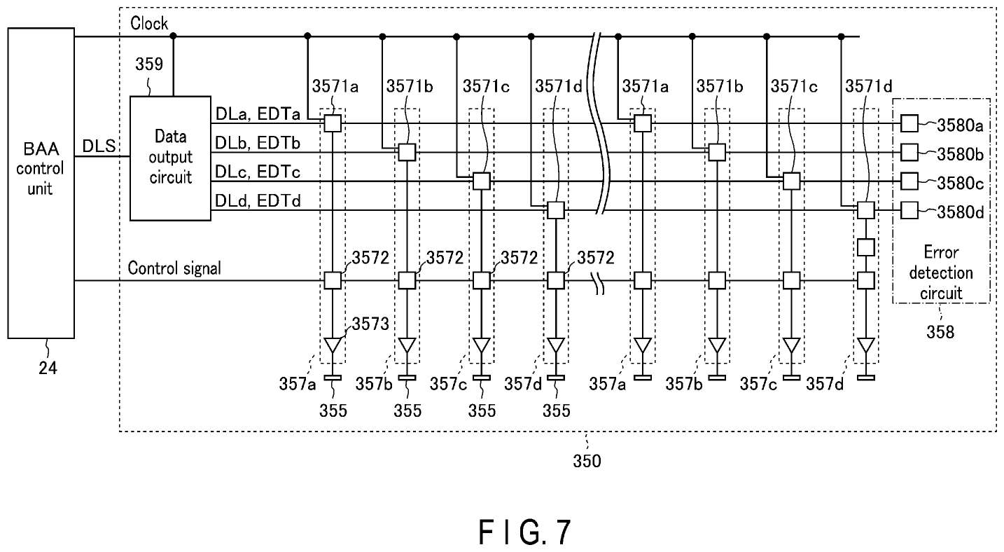

FIG. 7 is a more detailed circuit diagram of a part of the blanking aperture array mechanism 350 according to the first embodiment, and representatively shows elements directly or indirectly connected to one data output circuit 359. The portions connected to the other data output circuits 359 also have the elements and connections shown in FIG. 7.

As described above, a plurality of control data items DL are formed from the control data DLS. FIG. 7 shows an example of four control data items DL. The four control data items DL are referred to as “control data DLa, DLb, DLc, and DLd”. Each control circuit 357 receives control data DLa, DLb, DLc, or DLd. The transmitted error correction codes EDT for the control data DLa, DLb, DLc, and DLd may be referred to as “transmitted error correction codes EDTa, EDTb, EDTc, and EDTd”, respectively. The control circuits 357 that receive the control signals DLa, DLb, DLc, and DLd may be referred to as “control circuits 357a, 357b, 357c, and 357d”, respectively.

Each control circuit 357 includes a register (e.g., D-type flip-flop) 3571 (3571a, 3571b, 3571c, 3571d), at least one buffer 3572, and a level shifter 3573. FIG. 7 and the following description are based on an example in which each control circuit 357 includes one buffer 3572.

Each register 3571 and each buffer 3572 hold 1-bit data. In each control circuit 357, the output of the register 3571 is connected to the input of the buffer 3572. Each buffer 3572 receives a control signal from the BAA control unit 24, for example, and holds data received at the input based on the control signal, and outputs the held data based on the control signal. Each control circuit 357 may include a plurality of buffers 3572 connected in series.

In each control circuit 357, the output of the buffer 3572 is connected to the input of the level shifter 3573. The level shifter 3573 converts the voltage level of the received input and outputs a voltage having a magnitude corresponding to the input. The output voltage is applied to one electrode 355 to be controlled by the control circuit 357 that outputs the voltage. As described above, a potential difference is formed between the electrode 355 and the electrode 356 paired with the electrode 355 by applying the voltage to each electrode 355. The trajectory of the electron beam EBm entering the area between the electrodes 355 and 356 is bent by the potential difference, and the electron beam EBm is blanked.

The register 3571 receives, for example, a clock as a control signal from the BAA control unit 24. The register 3571 is connected to the data output circuit 359 by a signal line. The register 3571 receives the control data DL and the transmitted error correction code EDT for the control data DL from the data output circuit 359 on the signal line. The register 3571 holds the control data DL and the transmitted error correction code EDT that has been input from the data output circuit 359 based on the control signal, and outputs the held control data DL and the transmitted error correction code EDT to the buffer 3572 based on the control signal.

The register 3571 of the control circuit 357a is referred to as a register 3571a. Similarly, the register 3571 of the control circuit 357b, the register 3571 of the control circuit 357c, and the register 3571 of the control circuit 357d are referred to as a “register 3571b”, a “register 3571c”, and a “register 3571d”, respectively.

Each register 3571a is connected in series to a neighboring register 3571a by a signal line, and the registers 3571 connected in series constitute a shift register. In other words, the output of one register 3571a is directly connected to the input of another register 3571a. Similarly, the registers 3571b are connected in series to constitute a shift register, the registers 3571c are connected in series to constitute a shift register, and the registers 3571c are connected in series to constitute a shift register.

The error detection circuit 358 includes the same number of registers 3580 as the number of sets of control-data DL, in other words, the registers 3580a, 3580b, 3580c, and 3580d in the present example. The register 3580a receives an output of the register 3571a at the last stage of the serially connected registers 3571a. Similarly, the registers 3580b, 3580c, and 3580d receive an output of the last register 3571b of the serially connected registers 3571b, an output of the last register 3571c of the serially connected registers 3571c, and an output of the last register 3571d of the serially connected registers 3571d, respectively. The error detection circuit 358 calculates a calculated error detection code EDC for the data held in the register 3580.

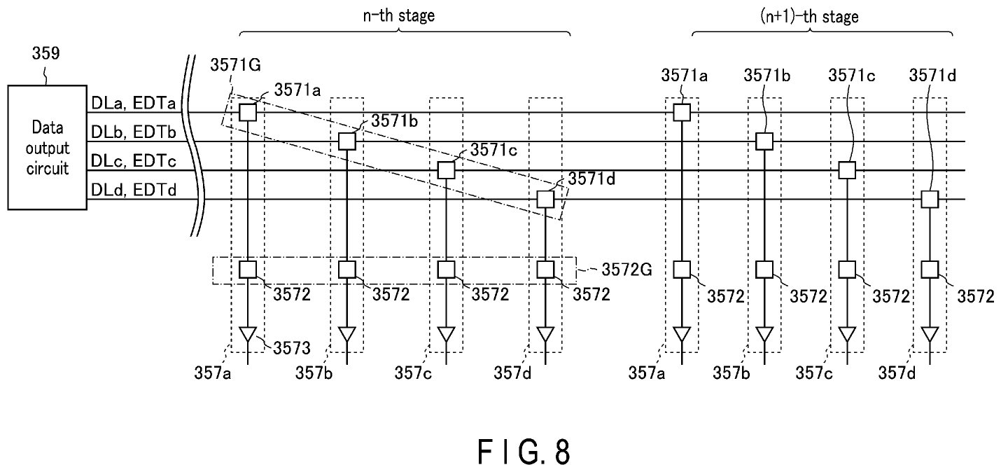

FIG. 8 shows a portion of FIG. 7. The register 3571a of the n-th stage, the register 3571b of the n-th stage, the register 3571c of the n-th stage, and the register 3571d of the n-th stage receive the control data DL for controlling the blanking of a plurality of electron beams EBm. Such control data DL is, for example, data for controlling blanking in one operation of any type. The registers 3571a, 3571b, 3571c and 3571d in one such stage receive the control data DLa, DLb, DLc and DLd constituting one control data item DL, and the registers 3571a, 3571b, 3571c and 3571d in the same stage are hereinafter referred to as a “register set 3571G”.

The control data DL in the registers 3571a, 3571b, 3571c, and 3571d of the n-th stage is transferred to the buffer set 3572G. The buffer set 3572G consists of a total of four buffers 3572 in each of the four control circuits 357 including the four registers 3571 of the register set 3571G in a certain stage.

### 1.2. Operation

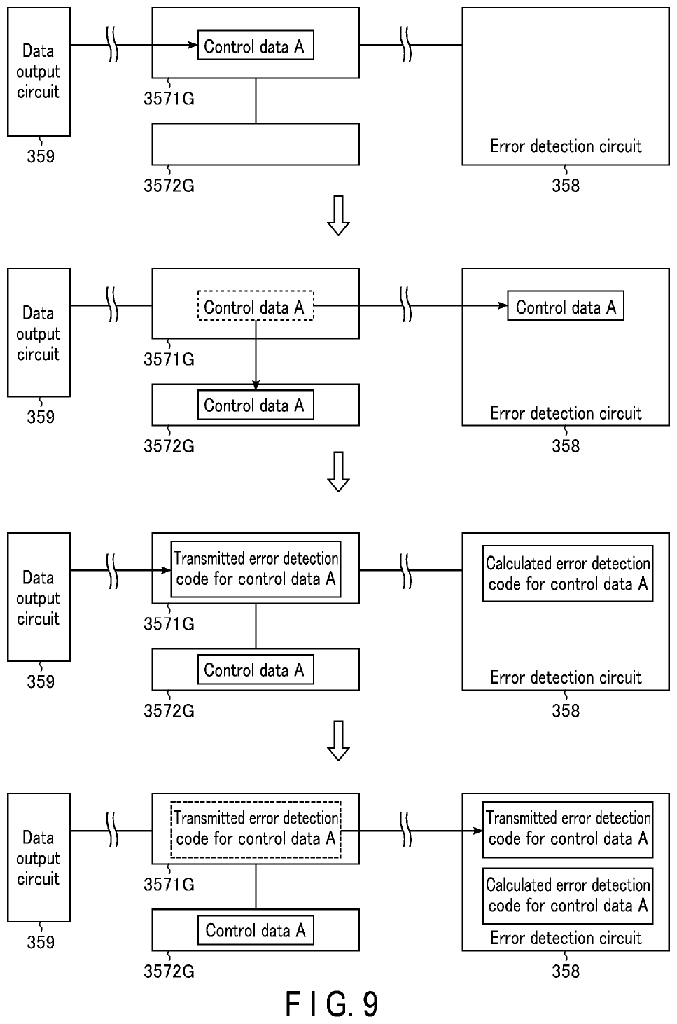

FIG. 9 schematically illustrates data transfer and generation in the writing apparatus 1 of the first embodiment. In particular, FIG. 9 shows the register set 3571G, the buffer set 3572G connected to the register set 3571G, and the error detection circuit 358.

As shown in the uppermost row of FIG. 9, the data output circuit 359 outputs control data A. The control data A is control data DL consisting of a certain bit string, consists of control data DLa, DLb, DLc, and DLd having a certain bit value, and consists of a plurality of bits associated with each other for controlling blanking of a certain plurality of electron beams EBm. For example, the control data A is data for controlling blanking in one operation of any type. The output control data A is received by the register set 3571G of a certain stage via the registers 3571.

As shown in the second row from the top of FIG. 9, the control data A is transferred to the buffer set 3572G included in the control circuit 357 including the register set 3571G that has received the control data A.

Specifically, of the control data A, the data received as the control data DLa is transferred to the buffer 3572 in the control circuit 357 where the register 3571a of the n-th stage is included. Similarly, of the control data A, the data received as the control data DLb is transferred to the buffer 3572 in the control circuit 357 where the register 3571b in the n-th stage is included. Of the control data A, the data received as the control data DLc is transferred to the buffer 3572 in the control circuit 357 where the register 3571c of the n-th stage is included. Of the control data A, the data received as the control data DLd is transferred to the buffer 3572 in the control circuit 357 where the register 3571d of the n-th stage is included. Thereafter, the control data A is transferred from the buffer set 3572G to the set of level shifters 3573 (not shown).

The control data A is transferred to the error detection circuit 358 via the registers 3571 at the stage after the stage of the register set 3571G. In other words, of the control data A, the data received as the control data DLa reaches the register 3580a of the error detection circuit 358 from the register 3571a of the n-th stage via the registers 3571a of the (n+1)-th stage and the subsequent stages. Of the control data A, the data received as the control data DLb reaches the register 3580b of the error detection circuit 358 from the register 3571b of the n-th stage via the registers 3571b of the (n+1)-th stage and the subsequent stages. Of the control data A, the data received as the control data DLc reaches the register 3580c of the error detection circuit 358 from the register 3571c of the n-th stage via the registers 3571c of the (n+1)-th stage and the subsequent stages. Of the control data A, the data received as the control data DLd reaches the register 3580d of the error detection circuit 358 from the register 3571d of the n-th stage via the registers 3571d of the (n+1)-th stage and the subsequent stages.

As illustrated in the third row from the top of FIG. 9, the error detection circuit 358 calculates an error detection code (calculated error detection code EDC) for the control data A. The data output circuit 359 calculates an error detection code (transmitted error detection code EDT) for the control data A and outputs the transmitted error detection code EDT for the control data A. The transmitted error detection code EDT for the control data A consists of transmitted error detection codes EDTa, EDTb, EDTc, and EDTd for the control data DLa, DLb, DLc, and DLd constituting the control data DLa. The transmitted error detection code EDT for the control data A is received by the register set 3571G. On the other hand, the transmitted error detection code EDT for the control data A is not transferred to the buffer set 3572G, unlike the control data DL (for example, the control data A). For this purpose, when the transmitted error detection code EDT is held in the register 3571, the BAA control unit 24 does not supply the control signal, which is described with reference to FIG. 7, to the buffer set 3572G that instructs taking in data.

As shown in the lowermost row of FIG. 9, the transmitted error detection code EDT for the control data A is received by the error detection circuit 358 via the registers 3571 at a stage subsequent to the stage of the register set 3571G, similarly to the case of the control data DL.

FIG. 9 shows an example in which the transmitted error detection code EDT for the control data A is output from the data output circuit 359 immediately after the control data A. However, the timing at which the transmitted error detection code EDT is output is not limited to the example of FIG. 9. For example, the transmitted error detection code EDT for the control data A may be output prior to the control data A. Other control data and/or another transmitted error detection code EDT may be output between the control data A and the transmitted error detection code EDT for the control data A.

### 1.3. Advantages (Advantageous Effects)

The blanking aperture array mechanism 350 includes the error detection circuit 358, and the error detection circuit 358 receives control data DL supplied to the level shifter 3573, calculates a calculated error detection code EDC from the received control data DL, receives a transmitted error detection code EDT for the control data DL, and compares the calculated error detection code EDC with the transmitted error detection code EDT. The transmitted error detection code EDT and the calculated error detection code EDC for certain control data DL should match if the control data DL is correctly transmitted from the data output circuit 359 to the error detection circuit 358. Therefore, a match between the calculated error detection code EDC and the transmitted error detection code EDT indicates that the registers 3571 connected in series are in a normal state. Therefore, by comparing the calculated error detection code EDC with the transmitted error detection code EDT, it is possible to check if all the registers 3571 that receive the control data DL that is output from the data output circuit 359 are in a normal state.

The transfer of data necessary for such a test only includes the transfer of the transmitted error detection code EDT additionally to the transfer of the control data DL in the registers 3571 connected in series in the case where the first embodiment is not applied. In other words, the transmitted error detection code EDT can be transferred only by being inserted into the control data DL. The transmission error detection code EDT consists of only a few bits. Therefore, the transfer of the control data DL, and in turn, the writing, can be suppressed from being hindered to a great extent, due to the inspection of the data. In other words, it is possible to inspect the path for transferring the control data DL during writing without greatly hindering the progress of writing carried out in the case where the first embodiment is not applied.

### 2. Second Embodiment

The second embodiment is different from the first embodiment in the configuration of the blanking aperture array mechanism 350 and points related thereto. The second embodiment is the same as the first embodiment in other respects. Hereinafter, the configuration and operation of the second embodiment will be described mainly in terms of differences from the first embodiment.

### 2.1. Configuration

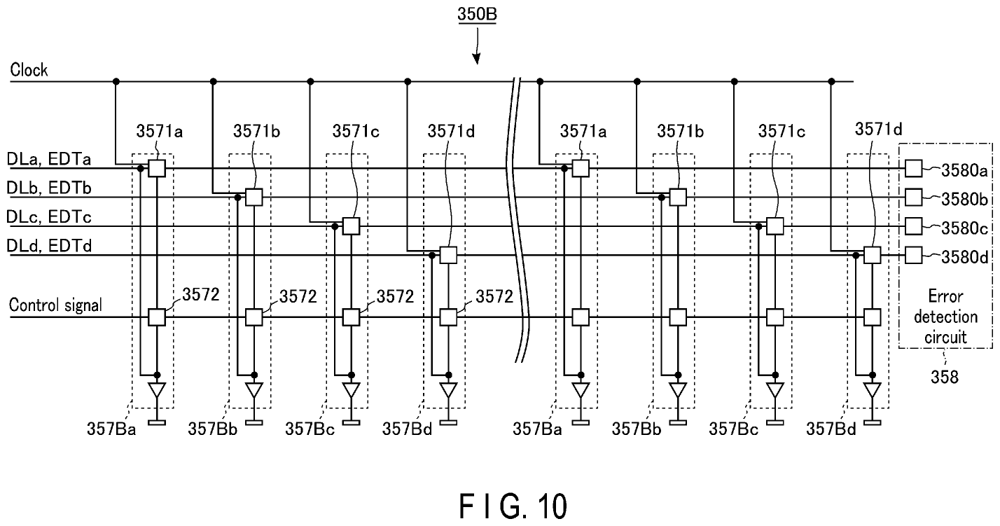

FIG. 10 is a more detailed circuit diagram of the blanking aperture array mechanism 350 according to the second embodiment, and representatively shows elements directly or indirectly connected to one data output circuit 359. The blanking aperture array mechanism 350 of the second embodiment may be referred to as a “blanking aperture array mechanism 350B” in order to distinguish it from the blanking aperture array mechanism 350 of the first embodiment.

The blanking aperture array mechanism 350B differs from the blanking aperture array mechanism 350 of the first embodiment in the details of the control circuit 357. The control circuit 357 of the second embodiment may be referred to as a control circuit 357B in order to distinguish it from the control circuit 357 of the first embodiment.

In each control circuit 357B, the buffer 3572 is further connected at its output to the input of the registers 3571 in that control circuit 357B. If each control circuit 357 includes a plurality of buffers 3572 connected in series, the output of the buffer 3572 of the last stage is connected to the register 3571.

The description so far relates to an example in which the output of the buffer 3572 is further connected to the input of the register 3571 in all the control circuit 357B. The embodiment is not limited to this configuration, and the output of the buffer 3572 may be further connected to the input of the register 3571 in the control circuit 357B only in one or more of all the control circuits 357B.

### 2.2. Operation

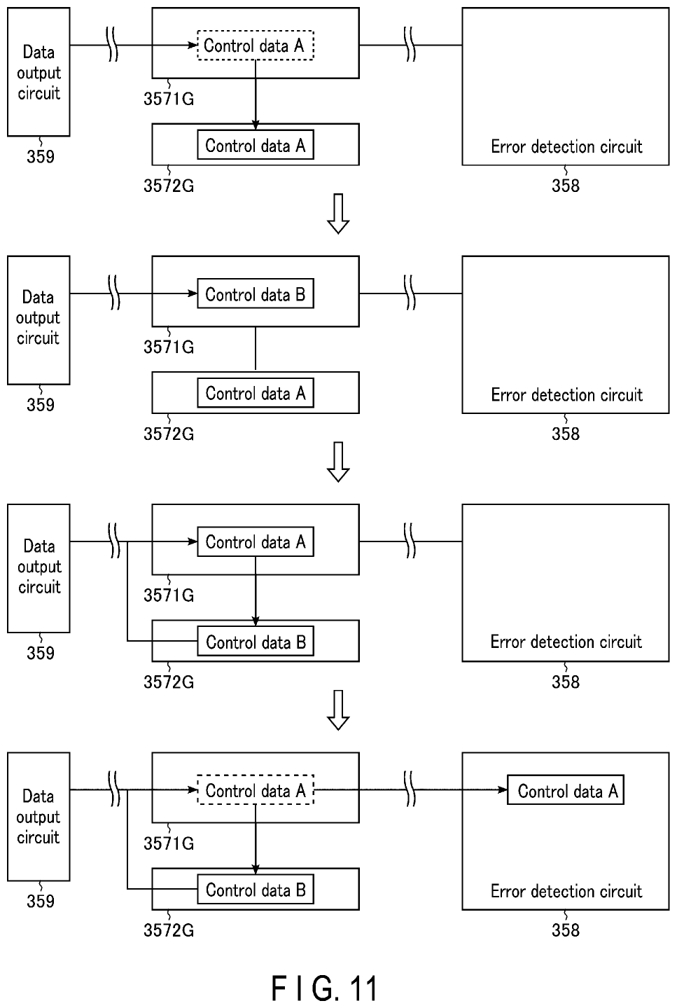

FIG. 11 schematically illustrates data transfer and generation in the writing apparatus 1 of the second embodiment. In particular, FIG. 11 shows the register set 3571G, the buffer set 3572G connected to the register set 3571G, and the error detection circuit 358.

As shown in the uppermost part of FIG. 11, the control data A is received by the register set 3571G and transferred to the buffer set 3572G.

As shown in the second row from the top of FIG. 11, the control data B is received by the register set 3571G, and the control data A is transferred to the buffer set 3572G.

As shown in the third row from the top of FIG. 11, the control data A is transferred to a set of level shifters 3573 (not shown) and is transferred again to the register set 3571G. At the same time, the control data B is transferred to the buffer set 3572G.

As shown in the lowermost part of FIG. 12, the control data A in the register set 3571G is transferred to the error detection circuit 358 via the register 3571 in the stage after the stage of the register set 3571G, as described with reference to FIG. 9 of the first embodiment.

Thereafter, the same processing as the processing described with reference to the third row from the top and the lowermost row of FIG. 9 of the first embodiment is performed on the control data A. That is, the calculated error detection code EDC for the control data A is calculated by the error detection circuit 358, and the transmitted error detection code EDT for the control data A is transferred from the data output circuit 359 to the error detection circuit 358 via the registers 3571.

The error detection circuit 358 compares the calculated error detection code EDC with the transmitted error detection code EDT for the control data A thus obtained, as in the first embodiment.

### 2.3. Advantages

According to the second embodiment, the error detection circuit 358 compares the calculated error detection code EDC with the transmitted error detection code EDT, similarly to the first embodiment. Therefore, the same advantages as those of the first embodiment can be achieved.

Further, each control circuit 357B includes a register 3571 connected to the output of the buffer 3572 of the control circuit 357B, and the error detection circuit 358 calculates the calculated error detection code EDC from the control data DL received from the buffer 3572 via the register 3571. If the control data DL in a certain register 3571 is correctly transmitted to the buffer 3572, the form of the control data DL should match that of the control data received by this register 130. Therefore, a match between the calculated error detection code EDC and the transmitted error detection code EDT generated as in the second embodiment indicates that the buffer 3572, in addition to the registers 3571, connected in series is in a normal state. Therefore, by the comparison between the calculated error detection code EDC and the transmitted error detection code EDT in the second embodiment, it is possible to check if all the registers 3571 that receive the control data DL output from the data output circuit 359 and all the buffers 3572 that transmit the control data DL are in a normal state.

The first and second embodiments have been described based on the example in which the blanking aperture array mechanisms 350 and 350B are used in the writing apparatus 1, but the present invention is not limited to this example. The blanking aperture array mechanisms 350 and 350B may be used in an inspection apparatus.

The present invention is not limited to the above-described embodiments, and can be modified in various manners in practice when implementing the invention without departing from the gist of the invention. Moreover, the embodiments can be suitably combined; in that case, the combined advantages are obtained. Furthermore, the above-described embodiments include various inventions, and a variety of inventions can be derived by suitably combining structural elements disclosed in connection with the embodiments. For example, if the object of the invention is achieved and the advantages of the invention are attained even after some of the structural elements disclosed in connection with the embodiments are deleted, the structure made up of the resultant structural elements can be extracted as an invention.

What is claimed is:

1. A blanking aperture array system used in a multi-charged particle beam irradiation apparatus, the blanking aperture array system comprising:
a data output circuit configured to output first data, which is one of a plurality of control data items used in beam irradiation, and a first error detection code for detecting an error in the first data generated from the first data;
a shift register that includes a plurality of registers connected in series and is configured to transfer the first data and the first error detection code that are input from the data output circuit;
a buffer configured to receive the first data that is output from a first register from the first register, the first register being one of the plurality of registers;
an electrode configured to receive a voltage based on the first data that is output from the buffer; and
an error detection circuit configured to:
receive the first data and the first error detection code from a register of a last stage among the plurality of registers;
generate a second error detection code for detecting an error in the first data from the first data received from the register of the last stage; and
generate a detection signal indicating a match if the first error detection code from the register of the last stage and the second error detection code match and indicating a mismatch if the first error detection code from the register of the last stage and the second error detection code do not match.

2. The blanking aperture array system of claim 1, wherein
the first data and the first error detection code are shifted at a same time as when second data is sent into the shift register, and are input to the error detection circuit input, and
the second data is next control data.

3. The blanking aperture array system according to claim 1, further comprising a control device that outputs the first data and the second error detection code to the data output circuit.

4. A blanking aperture array system used in a multi-charged particle beam irradiation apparatus, the blanking aperture array system comprising:
a data output circuit that outputs first data, which is one of a plurality of control data items used in beam irradiation, and a first error detection code for detecting an error in the first data generated from the first data;
a shift register that includes a plurality of registers connected in series and is configured to transfer the first data and the first error detection code that are input from the data output circuit;
a buffer configured to receive the first data that is output from a first register from the first register, the first register being one of the plurality of registers;
an electrode that receives a voltage based on the first data that is output from the buffer; and
an error detection circuit configured to:
receive the first error detection code from a register of a last stage among the plurality of registers;
receive, from the register of the last stage, the first data that is output from the buffer, received by the first register, and transferred via the shift register;
generate a second error detection code for detecting an error in the first data from the first data received from the register of the last stage; and
generate a detection signal indicating a match if the first error detection code from the register of the last stage and the second error detection code match and indicating a mismatch if the first error detection code from the register of the last stage and the second error detection code do not match.

5. The blanking aperture array system of claim 4, wherein
the first data and the first error detection code are shifted at a same time as when second data is sent into the shift register, and are input to the error detection circuit input, and
the second data is next control data.

6. The blanking aperture array system according to claim 4, further comprising a control device that outputs the first data and the second error detection code to the data output circuit.

7. A charged particle beam writing apparatus comprising:
a movable stage;
a beam source configured to irradiate the stage with a charged particle beam;
the blanking aperture array system of claim 1 located between the beam source and the stage; and
a control device configured to output the first data and the second error detection code to the data output circuit.

8. A charged particle beam writing apparatus comprising:
a movable stage;
a beam source configured to irradiate the stage with a charged particle beam;
the blanking aperture array system of claim 2 located between the beam source and the stage; and
a control device configured to output the first data and the second error detection code to the data output circuit.

9. A charged particle beam writing apparatus comprising:
a movable stage;
a beam source configured to irradiate the stage with a charged particle beam;
the blanking aperture array system of claim 3 located between the beam source and the stage; and
a control device configured to output the first data and the second error detection code to the data output circuit.

10. A charged particle beam writing apparatus comprising:
a movable stage;
a beam source configured to irradiate the stage with a charged particle beam;
the blanking aperture array system of claim 4 located between the beam source and the stage; and
a control device configured to output the first data and the second error detection code to the data output circuit.

11. A charged particle beam writing apparatus comprising:
a movable stage;
a beam source configured to irradiate the stage with a charged particle beam;
the blanking aperture array system of claim 5 located between the beam source and the stage; and
a control device configured to output the first data and the second error detection code to the data output circuit.

12. A charged particle beam writing apparatus comprising:
a movable stage;
a beam source configured to irradiate the stage with a charged particle beam;
the blanking aperture array system of claim 6 located between the beam source and the stage; and
a control device configured to output the first data and the second error detection code to the data output circuit.
